(19) United States
(12) Patent Application Publication
(10) Pub. No.: US 2007/0214299 A1
(43) Pub. Date: Sep. 13, 2007

(54) COMPUTING SYSTEM AND I/O BOARD THEREOF

(76) Inventor: Chi-Jung Lo, Taipei (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/278,526

(22) Filed: May 12, 2006

(30) Foreign Application Priority Data
Mar. 8, 2006 (TW) 095107807

(51) Int. Cl. H05K 7/10

(52) U.S. Cl. 710/301

(57) ABSTRACT

A computing system and an I/O board thereof are disclosed. The computing system comprises at least a processor card including at least a processor unit, an expansion board including at least an expansion socket, and the I/O board including a south bridge chip, an I/O controller, and a plurality of I/O ports. The processor card, the I/O board, and the expansion board can be coupled by at least a processor unit bus connector and a plurality of interconnection bus connectors so as to enable the south bridge chip to communicate with the processor unit and the expansion socket.

### BACKGROUND OF THE INVENTION

1. Field of the Invention

The present invention relates to a computing system and a related I/O board.

2. Description of the Related Art

A multi-processor system allows the operating system to execute on a host with multiple processors, and efficiently utilizes the computing power of each processor. Such computing systems can simultaneously assign multiple programs to different processors to reduce execution time. As a result, communications between the processors and between any processor and other chipset become very important.

Because of continuous developments in signal transmission speeds, various interconnection technologies are available in high speed bus technologies, from chip-to-chip, board-to-board, and chassis-to-chassis. The most popular technologies are PCI, PCI-X, PCI-Express (PCI-E) and HyperTrasport™, and Rapid-IO. These high speed bus technologies are well known technologies, and require no further description.

Please refer to FIG. 1. In a prior art computing system 1, which comprises a plurality of processor cards 11, a base board 12, and a backplane 13. Each processor card 11 has a plurality of processors 110 (such as two CPUs) and memory 112 such as DIMM chips. In order to achieve high communication speeds between processors 110 on different processor cards 11, the base board 12 is used to support the processor card 11 and has buses (not shown) in series to connect each processor card 11.

As shown in FIG. 1, in the prior art computing system 1, a south bridge chip 134, a tunnel bridge chip 136, an I/O controller 138, various input/output (I/O) connection ports 131, and an expansion socket 132 are all designed on the expansion board 13. The I/O connection port 131 comprises connection ports for USB, PS/2, audio, Internet, and the like; the I/O connection port 131 is controlled by the I/O controller 138 to provide peripheral expansion functions. The expansion socket 132 utilizes the tunnel bridge chip 136 to provide the expansion card functionalities. Communication between the backplane 13 and the processor 110 requires a special connector 14, such as an HTX-Pro interface connector, between the backplane 13 and the base board 12 to provide high speed transmission capabilities.

In additional to the special connector, the computing system 1 has less flexibility in terms of component compatibilty. Since the south bridge chip 134, the tunnel bridge chip 136, the I/O controller 138, the various I/O connection ports 131, and the expansion socket 132 are all disposed on the expansion board 13, it is impossible for the designer or the user to change any element on the expansion board 13 for upgrading system or changing specification. Another problem of the computing system 1 is that it is hard to disassemble. The expansion board 13 and the base board 12 are fixed in the case and connected together in a parallel board-to-board manner, which create difficulty in disassembly and reduce connection reliability of the connector 14.

Furthermore, with the plurality of processors 110, the computing system 1 requires a fan 15 for cooling; however, the board-to-board structure between the expansion board 13 and the base board 12 obstructs the cooling air flow.

Therefore, it is desirable to provide a computing system and related I/O board to mitigate and/or obviate the aforementioned problems.

### SUMMARY OF THE INVENTION

A main objective of the present invention provides a computer system and related I/O board. Another objective of the present invention is to provide an upgradeable I/O board and related computer system, and the computer system has good cooling effect with high speed transmission.

An embodiment of the present invention provides a computing system. The computing system comprises at least one processor card, an I/O board, and an expansion board. Each processor card has at least one processor. The expansion board comprises at least one expansion socket, at least one processor unit bus connector, and a plurality of interconnection bus connectors board. For example, the expansion socket can be a PIC-E or a PCI-X expansion socket.

The I/O board has a south bridge chip, an I/O controller, and a plurality of I/O ports. The I/O ports comprise a PS/2 connection port, a USB connection port, a LAN connection port, an IDE connection port, a SATA connection port, an audio connection port, or a disk connection port. The south bridge chip is electrically connected to the processor and the I/O controller, and at least one of the I/O ports is electrically connected to the I/O controller. The processor bus connector is used for accepting a processor card, and the plurality of interconnection bus connectors are used for accepting the I/O board to provide communication among the processor card, the I/O board, and the expansion board.

In this embodiment, the processor can be an AMD Operon™ processor, therefore, each processor can be connected to a memory and transmit information to the south bridge chip without a north bridge chip.

The processor bus connector on the expansion board can provide a dual unidirectional point-to-point transmission protocol, such as transmissions that obey the HyperTransport™ transmission protocol, and the processor bus connector has a physical contour of a PCI-E connector. Correspondingly, different processors on the same processor card communicate via dual unidirectional point-to-point transmissions as well.

The plurality of interconnection bus connectors comprise at least one dual unidirectional point-to-point transmission connector and at least one expansion interconnection connector (such as a PCI-E connector or a PCI-X connector). Correspondingly, the I/O board comprises at least one dual unidirectional point-to-point transmission interface and at least one expansion interconnection interface (such as a PCI-E interface or a PCI-X interface). The dual unidirectional point-to-point transmission interface and the expansion interconnection interface may be respectively inserted into the dual unidirectional point-to-point transmission connector and the expansion interconnection connector for electrically connection. The dual unidirectional point-to-point transmission connector obeys the HyperTransport™ transmission protocol.

The dual unidirectional point-to-point transmission connector has the PCI-E connector physical contour design, an engineer needs only to define the internal pins of the dual unidirectional point-to-point transmission connector instead of a new connector, and hence manufacturing costs can be reduced because of the PCI-E connector physical contour design.

In the embodiment of the present invention, the expansion board comprises at least one tunnel bridge chip, which can convert communications of one protocol type with a different type of communication protocol; in other words, when an expansion card is plugged into the expansion socket, the tunnel bridge chip enables the various expansion cards to communicate with the computing system.

The processor card and the I/O board should be placed parallel with each other to provide for better cooling air flow.

In another embodiment of the present invention, the processor card and the expansion board are inserted on the I/O board. Therefore, in this embodiment, the I/O board further comprises the processor bus connector and the interconnection bus connectors, which can be used for accepting the processor card and the expansion board.

In a third embodiment, the processors are designed on the expansion board, thus the processor, the tunnel bridge chip, and the expansion socket are all disposed on the expansion board, and the interconnection bus connectors are also disposed on the expansion board for accepting the I/O board.

As above mentioned, the present invention also provides an embodiment of an I/O board, which can be applied on the above-mentioned computing system.

Other objects, advantages, and novel features of the invention will become more apparent from the following detailed description when taken in conjunction with the accompanying drawings.

### BRIEF DESCRIPTION OF THE DRAWINGS

FIG. 1 is a schematic drawing of a prior art computing system.

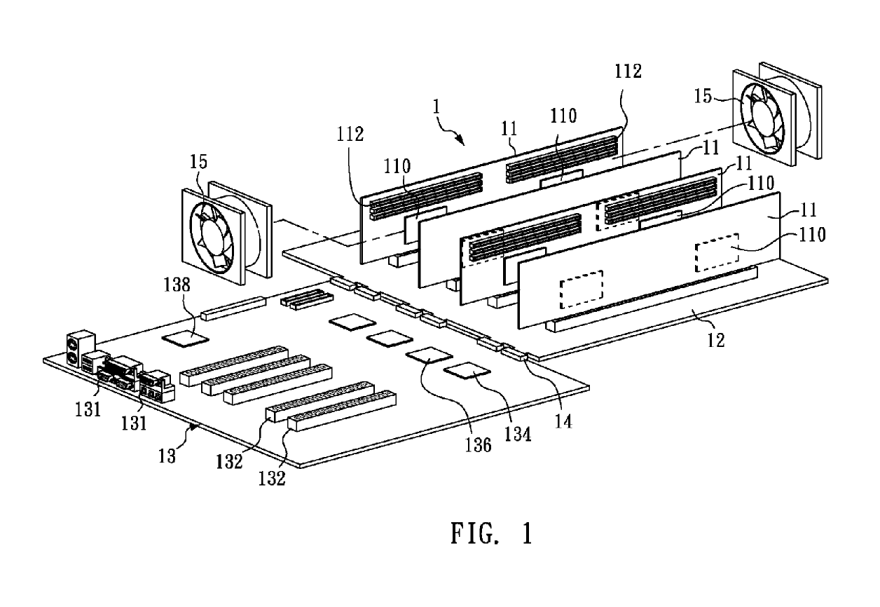

FIG. 2 is a schematic drawing showing an I/O board in a computing system according to an embodiment of the present invention.

FIG. 3 is block drawing showing a processor card utilizing a dual unidirectional point-to-point transmission protocol according to the present invention.

FIG. 4 is a schematic drawing showing an I/O board in a computing system according to another embodiment of the present invention.

FIG. 5 is a schematic drawing showing an I/O board in a computing system according to yet another embodiment of the present invention.

### DETAILED DESCRIPTION OF THE PREFERRED EMBODIMENT

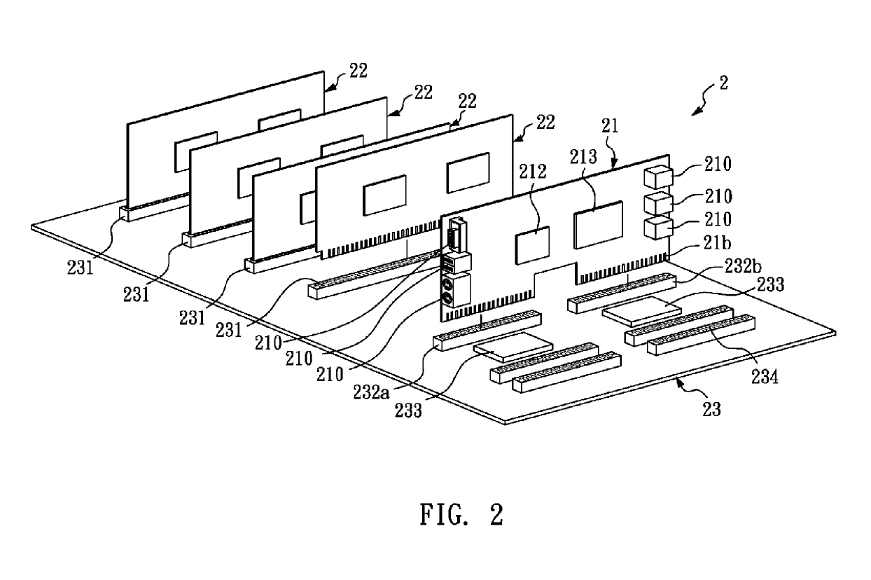

Please refer to FIG. 2. FIG. 2 is a schematic drawing showing an I/O board in a computing system according to an embodiment of the present invention. A preferred embodiment of the present invention provides a computing system 2 with an I/O board 21. The I/O board 21 comprises a south bridge chip 212, an I/O controller 213, and a plurality of I/O ports 210. The plurality of I/O ports 210 preferably include a PS/2 connection port, a USB connection port, a LAN connection port, an IDE connection port, a SATA connection port, an audio connection port, a disk connection port, and/or other suitable communication ports to support peripheral functions. Any number and type of I/O port 210 may be employed in the present invention for more flexible and upgradeable.

The computing system 2 comprises at least one processor card 22, the I/O board 21 and an expansion board 23. Each processor card 22 has at least one processor 220; for example, each processor card 22 may have two processors 220 thereon. In the case of computing system 2 having eight processors, there may be four processor cards 22 in the computing system 2, and each processor card 22 may have two processors 220 thereon. Alternatively, there may be two processor cards (not shown), with each processor card having four processors (not shown). In other words, the present invention supports various types and numbers of processor cards 22 or processors 220.

The expansion board 23 comprises at least one expansion socket 234, at least one processor bus connector 231 and a plurality of interconnection bus connectors 232a, 232b. The processor bus connector 231 can be used for accepting the processor card 22, and therefore the number of processor bus connectors 231 corresponds to the number of processor cards 22. The interconnection bus connectors 232a, 232b comprise at least one dual unidirectional point-to-point transmission connector 232a and at least one expansion interconnection connector 232b (such as a PCI-E connector or a PCI-X connector), which can be used for accepting the I/O board 21 to connect the processor card 22, the I/O board 21, and the expansion board 23. Correspondingly, the I/O board 21 comprises at least one dual unidirectional point-to-point transmission interface 21a and at least one expansion interconnection interface 21b (such as a PCI-E interface or a PCI-X interface); the dual unidirectional point-to-point transmission interface 21a and the expansion interconnection interface 21b may be respectively inserted into the dual unidirectional point-to-point transmission connector 232a and the expansion interconnection connector 232b for electrically connection.

The south bridge chip 212 is electrically connected to the processors 220 and the I/O controller 213, and at least one of the I/O ports 210 is electrically connected to the I/O controller 213. The I/O controller 213 can control communication between the I/O port 210 and the expansion socket 234. For example, when the computing system 2 is communicated with other devices (such as a USB device, an Internet device, a hard disk device, a CD drive, a DVD drive, etc.), the processors 220 on each processor card 22 can establish communication via the various I/O ports 210.

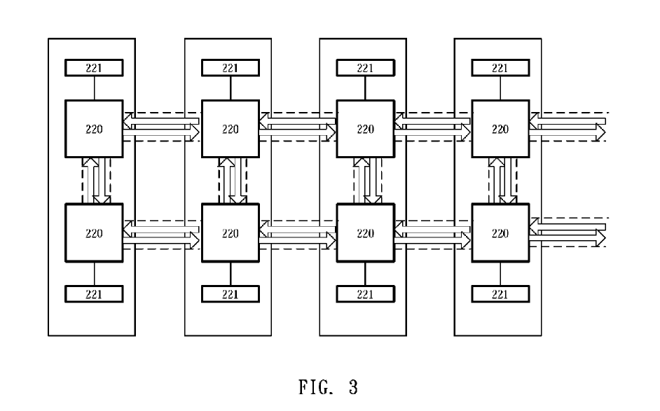

In a preferred embodiment of the present invention, each processor 220 has a memory controller (not shown) so that the processors 220 can be connected directly to memory 221 (as shown in FIG. 3).

In this embodiment, each processor bus connector 231 on the expansion board 23 can provide a dual unidirectional point-to-point transmission protocol, such as transmissions that obey the HyperTransport™ transmission protocol, and each processor bus connector 231 has a PCI-E connector physical contour. Correspondingly, different processors 220 on the same processor card 22 communicate via dual unidirectional point-to-point transmissions as well. Please refer to FIG. 3. Different processors 220 on the same processor card 22 communicate via the dual unidirectional point-to-point transmissions, and different processors 220 on different processor cards 22 also communicate via the dual unidirectional point-to-point transmission protocol. The dual unidirectional point-to-point transmission connector 232a is compatible with the HyperTransport™ transmission protocol to increase transmission speeds.

Since the dual unidirectional point-to-point transmission connector 232a has the PCI-E connector physical contour design, an engineer needs only to define the internal pins (not shown) of the dual unidirectional point-to-point transmission connector 232a and not a new connector, and hence manufacturing costs can be reduced because of using the PCI-E connector physical contour design.

In the embodiment of the present invention, the expansion board 23 comprises at least one tunnel bridge chip 233, which can convert communications of one protocol type with a different type of communication protocol; in other words, when an expansion card (not shown) is plugged into the expansion socket 234, the tunnel bridge chip 233 enables the various expansion cards to communicate with the computing system 2.

The processor cards 22 and the I/O board 21 should be placed parallel with each other to provide for better cooling air flow.

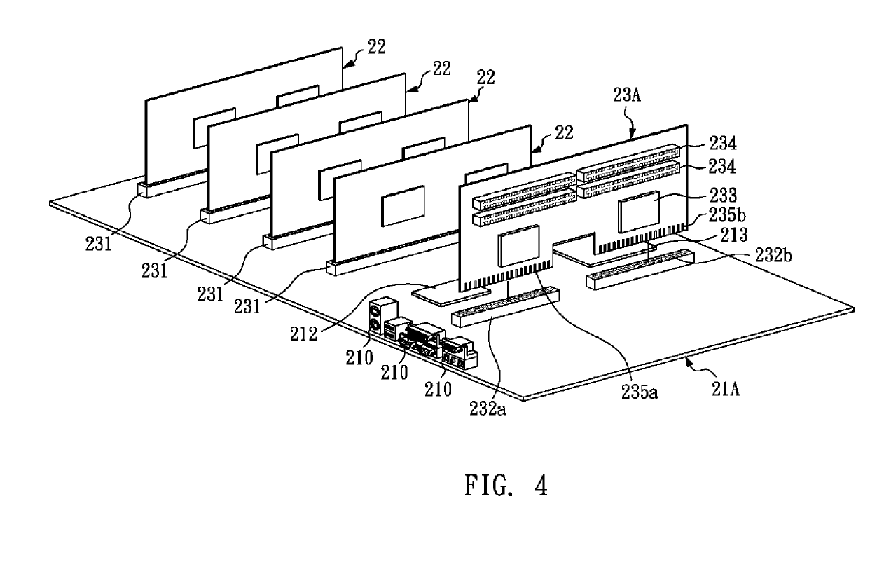

Please refer to FIG. 4. In another embodiment of the present invention, the processor card 22 and the expansion board 23A are inserted on the I/O board 21A. Therefore, in this embodiment, the I/O board 21A further comprises the processor bus connectors 231 and the interconnection bus connector 232a, 232b, which can be used for accepting the processor cards 22 and the expansion board 23A.

Similarly, the I/O board 21A further comprises the south bridge chip 212, the I/O controller 213, the plurality of I/O ports 210, and the plurality of I/O ports 210 preferably include a PS/2 connection port, a USB connection port, a LAN connection port, an IDE connection port, a SATA connection port, an audio connection port or a disk connection port. Each processor card 22 has at least one processor 220 thereon.

The plurality of interconnection bus connectors 232a, 232b comprise at least one dual unidirectional point-to-point transmission connector 232a and at least one expansion interconnection connector (such as a PCI-E connector or a PCI-X connector), which can be used for accepting the expansion board 23A to connect the processor card 22, the I/O board 21, and the expansion board 23A.

The expansion board 23A comprises a tunnel bridge chip 233 and at least one expansion socket 234. Furthermore, the expansion board 23A further comprises at least one dual unidirectional point-to-point transmission interface 235a and at least one expansion interconnection interface 235b (such as a PCI-E interface or a PCI-X interface); the dual unidirectional point-to-point transmission interface 235a and the expansion interconnection interface 235b can be respectively inserted into the dual unidirectional point-to-point transmission connector 232a and the expansion interconnection connector 232b for electrically connection.

Similarly, in this embodiment, the processor bus connector 231 can be used for accepting the processor card 22; therefore, the number of processor bus connectors 231 corresponds to the number of processor cards 22.

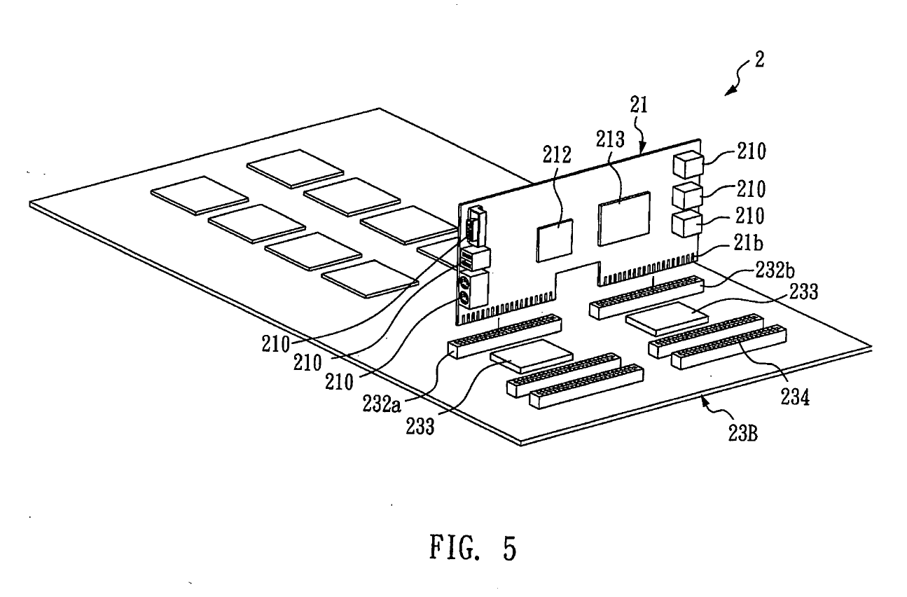

Please refer to FIG. 5. Furthermore, in a third embodiment, the processors 220 are designed onto the expansion board 23B, the processors 220, the tunnel bridge chip 233, and the expansion socket 234 are all disposed on the expansion board 23B. And, the interconnection bus connectors (comprising at least one processor bus connector 232a and at least one expansion interconnection connector 232b, such as a PCI-E connector or a PCI-X connector) are also disposed on the expansion board 23B for accepting the I/O board 21.

In this embodiment, the I/O board 21 further comprises the south bridge chip 212, the I/O controller 213, and the plurality of I/O ports 210, the plurality of I/O ports 210 preferably comprising a PS/2 connection port, a USB connection port, a LAN connection port, an IDE connection port, a SATA connection port, an audio connection port, or a disk connection port. Correspondingly, the I/O board 21 also comprises at least one dual unidirectional point-to-point transmission interface 21a and at least one expansion interconnection interface (such as a PCI-E interface or a PCI-X interface) 21b; the dual unidirectional point-to-point transmission interface 21a and the expansion interconnection interface 21b can be respectively inserted into the dual unidirectional point-to-point transmission connector 232a and the expansion interconnection connector 232b for electrically connection.

As indicated above, the I/O board 21 and/or 21A can be more flexible for supporting different computing systems 2, 2A, 2B with different case (not shown) sizes such as 2U-4U (1U is about 45 mm).

Although the present invention has been explained in relation to its preferred embodiment, it is to be understood that many other possible modifications and variations can be made without departing from the spirit and scope of the invention as hereinafter claimed.

What is claimed is:

1. A computing system comprising:
at least a processor card having at least a processor;
an I/O board having a south bridge chip, an I/O controller, and a plurality of I/O ports, the south bridge chip being electrically connected with the processor and the I/O controller, and at least a of the I/O ports being electrically connected to the I/O controller; and
an expansion board having an expansion socket, at least a processor unit bus connector, and a plurality of interconnection bus connectors, wherein the processor bus connector is used for accepting the processor card, and the plurality of interconnection bus connectors are used for accepting the I/O board to provide communication among the processor card, the I/O board, and the expansion board.

2. The computing system as claimed in claim 1, wherein the plurality of interconnection bus connectors comprise at least a expansion interconnection connector and at least a dual unidirectional point-to-point transmission connector.

3. The computing system as claimed in claim 2, wherein the dual unidirectional point-to-point transmission connector has a physical contour compatible with a PCI-E specification.

4. The computing system as claimed in claim 2, wherein the I/O board further comprises at least a dual unidirectional point-to-point transmission interface and at least an expansion interconnection interface, the dual unidirectional point-to-point transmission interface and the expansion interconnection interface capable of being respectively coupled to the dual unidirectional point-to-point transmission connector and the expansion interconnection connector for electrical connection.

5. The computing system as claimed in claim 4, wherein the expansion interconnection connector and the expansion interconnection interface are compatible with a PCI-X specification or a PCI-E specification.

6. The computing system as claimed in claim 1, wherein the I/O board further comprises a BIOS chip, a video chip, or an I/O hub chip.

7. The computing system as claimed in claim 1, wherein the I/O ports comprise a PS/2 connection port, a USB connection port, a LAN connection port, an IDE connection port, a SATA connection port, an audio connection port, or a disk connection port.

8. The computing system as claimed in claim 1, wherein the expansion board further comprises at least a tunnel bridge chip electrically connected to and between the south bridge chip and the expansion socket.

9. A computing system comprising:
at least a processor card having at least a processor;
an expansion board having at least an expansion socket; and
an I/O board having a south bridge chip, an I/O controller, a plurality of I/O ports, at least a processor bus connector, and a plurality of interconnection bus connectors; wherein the processor bus connector is used for accepting the processor card, and the plurality of interconnection bus connectors are used for accepting the I/O board to provide communication among the processor card, the I/O board, and the expansion board.

10. The computing system as claimed in claim 9, wherein the plurality of interconnection bus connectors comprise at least an expansion interconnection connector and at least a dual unidirectional point-to-point transmission connector.

11. The computing system as claimed in claim 10, wherein the dual unidirectional point-to-point transmission connector has a physical contour compatible with a PCI-E specification.

12. The computing system as claimed in claim 10, wherein the expansion board further comprises at least a dual unidirectional point-to-point transmission interface and at least an expansion interconnection interface, the dual unidirectional point-to-point transmission interface and the expansion interconnection interface respectively insertable into the dual unidirectional point-to-point transmission connector and the expansion interconnection connector to provide electrical connection.

13. The computing system as claimed in claim 12, wherein the expansion interconnection connector and the expansion interconnection interface are compatible with a PCI-X specification or a PCI-E specification.

14. An I/O board for a computing system comprising:
a plurality of I/O ports;
a south bridge chip; and
an I/O controller electrically connected to the south bridge chip and at least one of the I/O ports;
wherein the I/O board is electrically connected to an expansion board of the computing system to electrically connect the south bridge chip to at least a processor and at least an expansion socket of the computing system.

15. The I/O board as claimed in claim 14, wherein the expansion board further comprises at least a tunnel bridge chip electrically connected to and between the south bridge chip and the expansion socket.

16. The I/O board as claimed in claim 14, wherein the I/O ports comprise a PS/2 connection port, a USB connection port, a LAN connection port, an IDE connection port, a SATA connection port, an audio connection port or a disk connection port.

17. The I/O board as claimed in claim 14 further comprising at least a dual unidirectional point-to-point transmission interface and at least a expansion interconnection interface insertable on the expansion board to electrically connect the I/O board to the expansion board.

18. The I/O board as claimed in claim 17, wherein the expansion interconnection interface is compatible with a PCI-X specification or a PCI-E specification.

19. The I/O board as claimed in claim 17, wherein the processor is disposed on the expansion board or disposed on a processor card inserting on the expansion board.

20. The I/O board as claimed in claim 14 further comprising at least a dual unidirectional point-to-point transmission connector and at least an expansion interconnection connector utilized for the expansion board to be inserted thereon and enable the I/O board electrically connect to the expansion board.
